(19) United States
(12) Patent Application Publication
(10) Pub. No.: US 2025/0052272 A1
(43) Pub. Date: Feb. 13, 2025

(54) MULTI-ZONE COATINGS ON PARTS FOR GALLING PREVENTION AND HIGH-TEMPERATURE CHEMICAL STABILITY

(71) Applicant: Lam Research Corporation, Fremont, CA (US)

(72) Inventors: Rohit Ode, Portland, OR (US); Troy Alan Gomm, Tigard, OR (US)

(21) Appl. No.: 18/720,496

(22) PCT Filed: Dec. 14, 2022
(86) PCT No.: PCT/US2022/052877

§ 371 Date: Jun. 14, 2024

Related U.S. Application Data
(60) Provisional application No. 63/265,535, filed on Dec. 16, 2021.

(51) Int. Cl. F16B 33/06; F16B 33/00; H01J 37/32

(52) U.S. Cl. CPC F16B 33/06; F16B 33/008; H01J 37/32357; H01J 37/32853; H01J 37/32899; H01J 2237/3355

(57) ABSTRACT

Disclosed herein are fasteners for use in a semiconductor wafer process chamber. The fasteners may be used to secure hardware. The fasteners may include outermost surfaces that are provided by multiple different coatings, e.g., a hard coating and a dry lubricant coating. The hard coating may provide outermost surfaces of the fastener that are exposed to a plasma when a remote plasma clean is performed and may be used to prevent particle generation when the fastener is subjected to the remote plasma clean. The dry lubricant coating may provide outermost surfaces of a threaded portion of the fastener and may be used to prevent galling.

### RELATED APPLICATION(S)

An application data sheet is filed concurrently with this specification as part of the present application. Each application that the present application claims benefit of or priority to as identified in the concurrently filed application data sheet is incorporated by reference herein in its entirety and for all purposes.

### BACKGROUND

In semiconductor wafer processing, some process chambers may be used for deposition of gases onto a substrate, e.g. a semiconductor wafer. During the deposition process, process gases may be flowed across the substrate to deposit a layer of material onto the semiconductor wafer using a showerhead. Such gas may also flow to other areas of the chamber, often causing a film to be deposited on the chamber's interior surfaces. To remove the film, a chamber may undergo a remote plasma clean. In such a cleaning operation, a remotely generated plasma may be directed into the chamber through one or more inlets and caused to flow across various surfaces, thereby removing films that have been undesirably deposited on surfaces of the chamber.

### SUMMARY

In some implementations, a fastener having a head and a shank connected to a first side of the head may be provided. A first portion of the shank may be threaded, a first zone may extend from a second side of the head to at least the first side of the head, a second zone may cover at least a portion of the first portion, an outermost surface of the fastener in the first zone may be provided by a hard coating, and an outermost surface of the fastener in the second zone may be provided by a dry lubricant coating.

In some implementations of the fastener, the first portion may include the entire length of the shank.

In some implementations of the fastener, the first portion may be less than the entire length of the shank.

In some implementations of the fastener, the second zone may cover the entire first portion of the shank.

In some implementations of the fastener, the second zone may cover less than the entire first portion of the shank.

In some implementations of the fastener, the dry lubricant coating may be tungsten disulfide (WS₂).

In some implementations of the fastener, the dry lubricant coating may be one of the following: tungsten disulfide (WS₂), molybdenum disulfide (MS₂), tin disulfide (SnS₂), bismuth trisulfide (Bi₂S₃), antimony trisulfide (Sb₂S₃), or any combination of two or more thereof.

In some implementations of the fastener, the hard coating may be an alumina coating.

In some implementations of the fastener, the hard coating may be one of the following: alumina, yttria-stabilized zirconia (YSZ), yttrium aluminum garnet (YAG), yttrium aluminum monoclinic (YAM), yttrium aluminum perovskite (YAP), or any combination of two or more thereof.

In some implementations of the fastener, the head may be a socket head.

In some implementations of the fastener, the head may be a button head.

In some implementations of the fastener, the head may be a countersink head.

In some implementations of the fastener, the head may be a hexagonal head.

In some implementations of the fastener, the head may be a pan head.

In some implementations, a kit for use in a semiconductor wafer processing chamber may be provided. The kit may have at least four of the fasteners such as are described above.

In some implementations, an apparatus may be provided that includes a spindle having an indexer hub with a plurality of indexer arms extending therefrom and a plurality of fasteners with exposed heads supported by the indexer hub. Each fastener of the plurality of fasteners may have a shank connected to a first side of a head, a first portion of the shank may be threaded, a first zone may extend from a second side of the head to at least the first side of the head, a second zone may cover at least a portion of the first portion, an outermost surface of the fastener in the first zone may be provided by a hard coating, and an outermost surface of the fastener in the second zone may be provided by a dry lubricant coating.

In some implementations, the apparatus may further include a chamber with four wafer processing stations and the indexer hub may be in a central area of the chamber.

In some implementations, the apparatus may further include a remote plasma source, and the remote plasma source may be configured to deliver plasma into the chamber and onto the indexer hub.

In some implementations of the apparatus, the dry lubricant coating may be tungsten disulfide.

In some implementations of the apparatus, the hard coating may be an alumina coating.

### BRIEF DESCRIPTION OF DRAWINGS

Reference to the following Figures is made in the discussion below; the Figures are not intended to be limiting in scope and are simply provided to facilitate the discussion below.

FIG. 1 shows a top view of an example chamber with an example rotational indexer system.

FIG. 2 shows a cross-sectional view of an example chamber with an example rotational indexer system and example remote plasma clean system.

FIGS. 3-1 through 3-3 and 4-1 through 4-3, show example fasteners with example multi-zone coatings.

FIGS. 5-1 through 8-2 show example fasteners that may be used with multi-zone coatings.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

During semiconductor wafer processing, process gases are used to deposit thin films onto substrates, e.g., semiconductor wafers. Gases may be deposited using chemical vapor deposition (CVD), atomic layer deposition (ALD), or other process in a processing chamber. The processing chamber may have one or more wafer processing stations. In some embodiments, the processing chamber may have a single station. In other embodiments, the processing chamber may have multiple wafer processing stations. Each wafer processing station may have its own showerhead and pedestal. During deposition, gases are flowed from the showerhead onto a substrate supported by the pedestal. The gases, in addition to depositing a material layer on the substrate, may also deposit the material layer onto interior surfaces of the processing chamber, leaving a residue. This residue may cause substrates to become contaminated with contaminants during subsequent processing, e.g., due to flaking or release of other particulates from the residue; the residue may also start to interfere with the operation of other elements of the semiconductor processing chamber, e.g., sealing surfaces, rotational interfaces, etc.

To prevent such issues, cleaning methods may be used to remove residue inside the processing chamber. One cleaning method is a remote plasma clean, where a plasma is flowed into the processing chamber via one or more nozzles or openings from a remote plasma generator/source. The plasma reacts with the residue on the interior surfaces of the chamber, removing the residue and cleaning the processing chamber. When the plasma is flowed into the chamber, the plasma is at a high temperature, e.g., high enough to heat components that are directly impinged upon by the plasma to temperatures above 400° C. The high-temperature plasma may damage hardware causing the hardware to deteriorate and shed particles within the chamber.

In some embodiments of the processing chamber, the cleaning plasma is directed down onto the pedestals through a showerhead. But in some of Applicant's newer multi-station tools, the plasma is instead directed down into a central area of the chamber and onto a spindle of a rotational indexer and then deflected radially outwards to flow over the pedestals and chamber surfaces. The spindle may have fasteners that are thus exposed to the high-intensity, high-temperature plasma. Such exposure has caused issues, such as the shedding of particles within the chamber by the fasteners, not typically encountered in prior tools with remote plasma clean capability.

To reduce the shedding of particles within the chamber, hardware within the chamber, including threaded fasteners, may be made of and/or coated with a hard material that is resistant to chemical attack. For example, fasteners may be made of nickel-chromium-based superalloys, e.g., Inconel 625™, and may be coated with a hard coating. These superalloys, along with the hard coating, may exhibit reduced shedding of particles when exposed to a high-energy plasma, e.g., via the remote plasma clean. Thus, during wafer processing, the hardware may shed fewer particles when compared to hardware without corrosion-resistant material during cleaning operations by the remote plasma clean.

However, while such fasteners exhibited reduced shedding of particles, the inventor discovered that the threaded interface between these fasteners and the hardware they were threaded into were galling at high rates. The fasteners galled at increased rates because they were subjected to relatively large tensile loads and high temperatures, e.g., greater than 300° C. In such conditions, a higher preload may be desired for the fastener to secure the hardware at elevated temperatures (to offset potential preload loss due to thermal expansion), putting an even larger load on the fastener than might normally be used. In addition, the thermal expansion and contraction of the fastener may cause the mating surfaces of the fastener and the hardware to move relative to one another, generating additional frictional loads within the threaded interface. The elevated temperature that the fasteners are at may also place the fastener material at an increased risk of galling. All of these factors are believed to have led to an increased rate of galling in the threaded interface between the fasteners and the spindle. Thus, during servicing of semiconductor wafer processing chambers in which such fasteners need to be removed, the fasteners and/or the hardware they are threaded into may have to be replaced in their entirety. Such hardware can be costly—ranging up to $100 per fastener in some cases (this may include the cost of the fastener plus whatever anti-corrosion surface treatment needs to be performed).

The inventor came up with a solution of having dual-coated fasteners, i.e., an outermost surface of a first portion of the fastener provided by a first material and an outermost surface of a second portion of the fastener provided by a second material, used to secure hardware that may be exposed to a high-energy plasma source. Such fasteners have a hard coating of corrosion-resistant material on at least some of their surfaces which helps reduce particle shedding due to exposure to a high-energy plasma but may also include a dry lubricant coating on at least some of their threaded surfaces to reduce galling when mated with hardware. The hard coating may be a chemically resistant coating. In some cases, the coating may be a coating that is resistant or chemically inert to fluorine and oxygen radicals. For example, the hard coating may be a ceramic such as aluminum oxide (Al₂O₃). A list of example hard-coating materials is provided later below. The dual-coated fasteners have a hard, corrosion-resistant material provided to at least some, in some cases all, of the outermost surfaces of the fasteners exposed to the high-energy cleaning plasma when mounted in a semiconductor wafer chamber and a dry lubricant material provided to at least some of the outermost surfaces of the threads for reducing the thread friction, and thus reducing the chance of (or entirely preventing) galling when the fasteners are used to secure hardware within the chamber. It may be desirable that the dry lubricant is resistant to high temperatures, compatible in environments with fluorine and oxygen radicals, and/or minimally sheds particles. Generally speaking, the dry lubricant may have a higher hardness compared to the material of the part that the fastener mates with and/or has a relatively low friction coefficient.

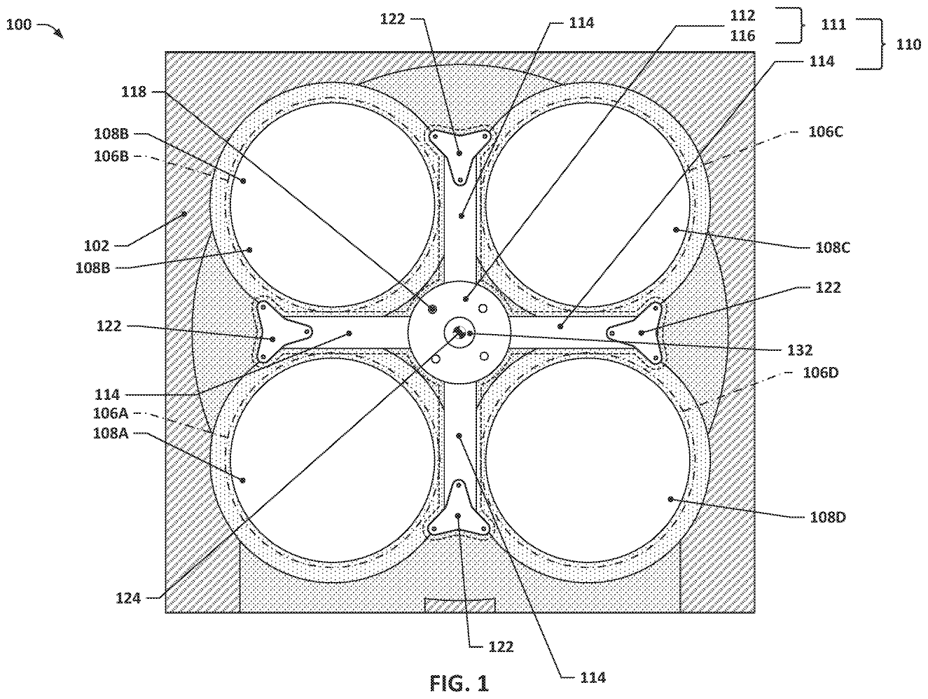

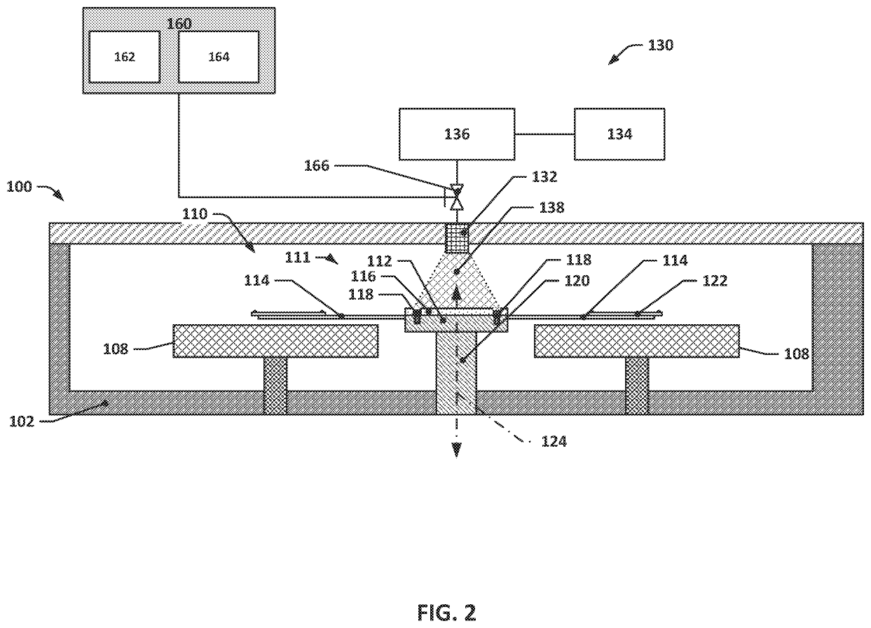

FIG. 1 depicts an example of a multi-station chamber with a rotational indexer system. In FIG. 1, a semiconductor processing tool 100 is shown that includes a chamber 102 that has four wafer processing stations 106A-D within it, each of which has a corresponding pedestal 108A-D which is configured to support a corresponding wafer. The semiconductor processing tool 100 may also include a rotational indexer system 110. The rotational indexer system 110 has a spindle 111 and a plurality of indexer arms 114 connected to the spindle. The rotational indexer system 110 is configured to rotate about a center axis 124 and may be used to transfer wafers (not shown) from a first wafer processing station to a second wafer processing during wafer processing. The spindle 111 is in a central part of the chamber 102. The spindle 111 has an indexer hub 112, a shaft (not shown, but see FIG. 2), and an indexer cover 116. Each of the indexer arms 114 is attached to and extends outwards from the indexer hub 112. On the distal end of each of the indexer arms 114 is a wafer support 122. The shaft connects the indexer hub 112 and a drive motor. The indexer cover 116 may be attached to the indexer hub 112 by one or more fasteners 118. In the embodiment shown, the indexer cover 116 is attached to the shaft by four fasteners 118; the same fasteners 118 may also be used to secure the indexer arms 114 in place.

The semiconductor processing tool 100 may also have a remote plasma clean system (not shown, but see FIG. 2). As discussed earlier, the remote plasma clean system may be used to clean residue from the inside of the processing chamber. The remote plasma clean system generates a plasma and provides the plasma to the chamber 102 through a nozzle 132. In the embodiment shown, the nozzle 132 is in the center area of the chamber and centered over the center axis 124 of the indexer hub 112.

FIG. 2 shows a cross-sectional view of the multi-station chamber 102 with the rotational indexer system 110. The rotational indexer system 110 has the spindle 111 and the indexer arms 114. The spindle 111 and the indexer hub 112 are in the center area of the chamber 102. The indexer arms 114 extend from the indexer hub 112 to locations that lie along a circle that passes through each of the wafer processing stations 106. FIG. 2 shows two of the four fasteners 118 which are used to connect the indexer cover 116 to the indexer hub 112 in this example (other implementations may use a larger or smaller number of such fasteners). Below the indexer hub 112 is an indexer shaft 120 which may be used to connect the indexer hub to a drive motor (not shown). Above the indexer cover 116 is the nozzle 132 for the remote plasma clean system 130. Each head of each fastener 118 is exposed to plasma flowed from the nozzle 132 during a cleaning operation. The heads of the fasteners are at locations that are relatively close to the nozzle such that the plasma has had little time to diffuse or cool down, so the head of each fastener is subjected to a hot and corrosive environment during a remote plasma clean.

The remote plasma clean system 130 has a gas source 134 and a plasma generator 136. The gas source 134, plasma generator 136, and the nozzle 132 are fluidically connected to each other. The plasma generator 136 is fluidically interposed between the gas source 134 and the nozzle 132. When the chamber is cleaned by remote plasma clean process, the gas source 134 supplies a gas to the plasma generator 136, where the gas is energized to create a plasma that may be at a high temperature, e.g., above 300° C. The plasma is sent to the nozzle 132 through a valve 166, where it is flowed into the chamber 102. The valve 166 may be controlled by a controller 160 with one or more processors 162 and a memory 164. The nozzle 132 may flow plasma into the chamber 102 directly onto the hardware directly beneath it. In the embodiment shown, the plasma may be flowed from the nozzle 132 directly onto a top surface of the indexer cover 116 and each of the heads of the fasteners 118. An example flow path 138 of the plasma flowed from the nozzle 132 is shown. In the example plasma flow path 138, the plasma hits the indexer cover 116 and each of the fasteners 118 before deflecting into the rest of the chamber 102.

The hardware components in the chamber 102, especially those directly under the plasma flow path, e.g., the indexer cover 116 and the fasteners 118, may be made of corrosion-resistant, hard material to prevent particle shedding. The fastener 118 may be made of a hard, corrosion-resistant material. Examples of hard, corrosion-resistant materials for fasteners include nickel-chromium-based superalloys, stainless steel, precipitation-hardened aluminum alloys, nitronic-strengthened steel alloy, and ceramics. Similarly, the non-fastener hardware components in the chamber 102 may be made of similar hard materials. In some embodiments, components such as the indexer cover 116 and the indexer hub 112 may be made of a corrosion-resistant material. Examples of hard materials used on non-fastener hardware components include nickel-chromium-based superalloys, stainless steel alloys, aluminum alloys, and ceramics. For example, the indexer cover 116 may be made of an aluminum alloy, such as aluminum 6061, and the indexer hub 112 may be made of the nickel-chromium-based superalloy. In another example, the indexer hub 112 is made of a stainless steel alloy. In some embodiments, the hardware may be coated with a hard material. For example, the indexer cover 116 made of aluminum 6061 may be coated with a ceramic material, such as Al₂O₃.

The fasteners 118 have an outermost surface. The fasteners 118 may have at least a first zone and a second zone, where the outermost surface within each zone is provided by a different coating. The first zone and the second zone may generally cover different portions of the threaded fastener, e.g., be non-overlapping. The outermost surface in the first zone is provided by a hard coating to protect the fastener from the plasma gas. Examples of hard coatings include coatings of alumina, yttria-stabilized zirconia (YSZ), yttrium aluminum garnet (YAG), yttrium aluminum monoclinic (YAM), yttrium aluminum perovskite (YAP), aluminum nitride, or any combination of two or more thereof. In some embodiments, the hard coating may be a plasma-spray coating. In some embodiments, the hard coating may be a uniform-thickness conformal coating, e.g., atomic-layer-deposition coating. The outermost surface in the second zone is provided by a dry lubricant coating to prevent galling or ruining of the threads when the fastener is mated to hardware components made of a similar hard material, such as the indexer hub 112. To be clear, the hard coating is not the same material as the dry lubricant coating and is not a dry lubricant coating. Even if the dry lubricant coating is a coating of a hard material, the hard coating of the first zone would be of a different hard coating than the hard coating/dry lubricant coating of the second zone. Examples of suitable dry lubricant coatings include tungsten disulfide (WS₂), molybdenum disulfide (MS₂), tin disulfide (SnS₂), bismuth trisulfide (Bi₂S₃), antimony trisulfide (Sb₂S₃), carbon, or any combination of two or more thereof. In some implementations, the dry lubricant coatings may not include carbon-based or carbon-including coatings. For example, embodiments used in a high-temperature environment, i.e., 400° C., may not include carbon coatings. However, embodiments used in a lower-temperature environment may include carbon, such as graphite, as the dry lubricant coating or an element thereof.

The first zone includes at least a portion of the head of the fastener. The second zone includes at least a part of the threaded shank of the fastener, generally starting at an end of the shank furthest away from the head of the fastener. In some embodiments, the second zone may cover an entire threaded portion of the fastener while the first zone may cover the unthreaded portion, i.e., the head and the unthreaded shank (if present). In some embodiments, the second zone may include a part of the threaded portion of the fastener and the first zone may include the rest of the fastener, i.e., the head, the unthreaded shank, and a second part of the threaded shank which is not covered by the second zone. In some embodiments, the first zone may include the head of the fastener, the second zone may include at least some of the threads of the fastener, and a third zone may be located between the first and second zones and may be uncoated or coated with a different material. The types of fasteners 118 and coatings will be discussed in further detail below.

FIGS. 3-1 through 3-3 show example fasteners with two coatings. In each figure is an example fastener 318 with a head 340 and a shank 342. The head 340 has a first side 350 and a second side 352. The shank 342 is connected to and extends from the first side 350 of the head 340. The shank 342 has a first end 346 and a second end 348. The second end 348 of the shank 342 is connected to the first side 350 of the head 340. Each fastener 318 has the shank 342 fully threaded, i.e., the shank 342 has threads that extend the full length of the shank. Each fastener 318 has an outer surface which has a first zone covered in a hard coating and a second zone covered in a dry lubricant coating. The first zone is shown in white and the second zone is shown in grey.

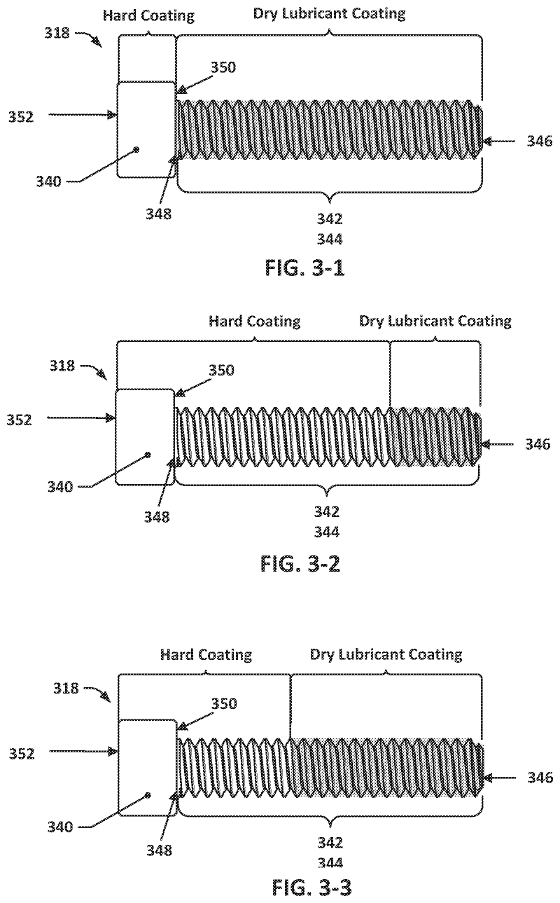

FIG. 3-1 shows a first example of a fastener 318 with outermost surfaces provided by two different coatings. In the first example, the outermost surface of the fastener that is provided by a hard coating, shown in white, includes the head 340 of the fastener 318, extending from the first side 350 of the head to the second side 352 of the head. In each example of a fastener 318 where the shank 342 is fully threaded, the hard coating provides the outermost surface of at least the head 340 of the fastener. The dry lubricant coating, shown in grey, provides the outermost surface of the entire threaded portion 344, and thus the entire shank 342, of the fastener 318. The dry lubricant coating starts at the first end 346 of the shank 342 and ends at the second end 348 of the shank.

FIG. 3-2 shows a second example of a fastener 318 with two coatings that provide the outermost surfaces of the fastener. In the second example, the hard coating, shown in white, provides the outermost surfaces of the head 340 of the fastener 318 and part of the shank 342. The hard coating extends from the second side 352 of the head, past the first side 350 of the head, past the second end 348 of the shank 342, and a significant way towards the first end 346 of the shank. The dry lubricant coating, shown in grey, provides the outermost surface of a small threaded portion 344 of the fastener 318. The dry lubricant coating starts at the first end 346 of the shank 342 and ends about a quarter way up the threaded portion 344. It may be desired that the hard coating provides the outermost surface of a significant amount of the threaded portion 344 to better protect the fastener from generating particles when exposed to a remote plasma clean. In these embodiments, the dry lubricant coating may provide the outermost surfaces of only a small part of the threaded portion 344 starting at the first end 346 of the shank 342. For example, the dry lubricant coating may provide the outermost surfaces of the first three to six threads from the first end 346 of the shank 342 and the hard coating may be used to provide the outermost surfaces of the rest of the fastener, i.e., from the fourth to seventh thread to the second side 352 of the head. In this example, the dry lubricant coating is placed on the threads that have the highest load, decreasing the potential of galling between the fastener 318 while the hard coating gives protection against high temperature on a significant portion of the fastener. It will be understood that in some embodiments, a hard coating may be provided to the entire fastener 318, i.e., the hard coating is provided from the first end 346 of the shank 342 to the second side 352 of the head 340. In these embodiments, the dry lubricant coating may be subsequently applied to the fastener 318 and may cover a portion of the hard coat on the shank 342, thereby providing the outermost surface of the fastener in that dry-lubricant-coated portion. For example, the hard coating may be applied to the entire fastener 318 and the dry lubricant coating then applied to the hard coating on a portion of the fastener having the threads 344, e.g., the first six threads from the first end 346 of the shank 342. Thus, it will be understood that any embodiment discussed herein may feature a second zone in which the dry lubricant coating is applied to a surface that already has a hard coating on it, thereby causing the outermost surfaces of the fastener to be provided by a dry lubricant coating in the second zone. It will also be understood that any embodiment discussed herein may feature a second zone in which there is no hard coating at all (or in which there is only a small amount of hard coating, e.g., in a transition region between the first zone and the second zone).

FIG. 3-3 shows a third example of a fastener 318 with two coatings that provide the outermost surfaces of the fastener. The third example shows a fastener with a hard coating that provides the outermost surfaces of the head 340 and the threaded portion 344 and a dry lubricant coating that provides the outermost surfaces of the threaded portion from the end of the hard coating to the first end 346 of the shank 342. The hard coating extends from the second side 352 of the head, past the first side 350 of the head, past the second end 348 of the shank 342 and partially towards the first end 346 of the shank. The dry lubricant coating, shown in grey, covers a part of the threaded portion 344 of the fastener 318. The dry lubricant coating starts at the first end 346 of the shank 342 and ends about a little past halfway up the thread 344.

FIGS. 4-1 through 4-3 show another set of example fasteners according to the present disclosure. The fasteners in FIGS. 4-1 through 4-2 may be similar in many respects to the fasteners of FIGS. 3-1 through 3-3 discussed earlier but may also differ in several respects. Structures or elements shown in FIGS. 4-1 through 4-3 that are similar to corresponding structures discussed earlier with respect to FIGS. 3-1 through 3-3 are indicated with callouts having the same last two digits. It may be assumed that such structures or elements referenced by callouts in FIGS. 3-1 through 3-3 with the same last two digits as in FIGS. 4-1 through 4-3 are similar to the corresponding structures in FIGS. 4-1 through 4-3, and the description of such elements with respect to FIGS. 3-1 through 3-3 is equally applicable to those corresponding elements in FIGS. 4-1 through 4-3 unless otherwise indicated.

FIGS. 4-1 through 4-3 each have a fastener 418 with a shank 342 that is partially threaded, i.e., the shank 442 has a non-threaded portion 454. The threaded portion 444 and non-threaded portion 454 meet at a boundary 456 which is partway between the first end 446 and the second end 448 of the shank 442. Each fastener 418 has a first zone in which the outermost surfaces of the fastener are provided by a hard coating and a second zone in which the outermost surfaces of the fastener are provided by a dry lubricant coating. The first zone is shown in white and the second zone is shown in grey.

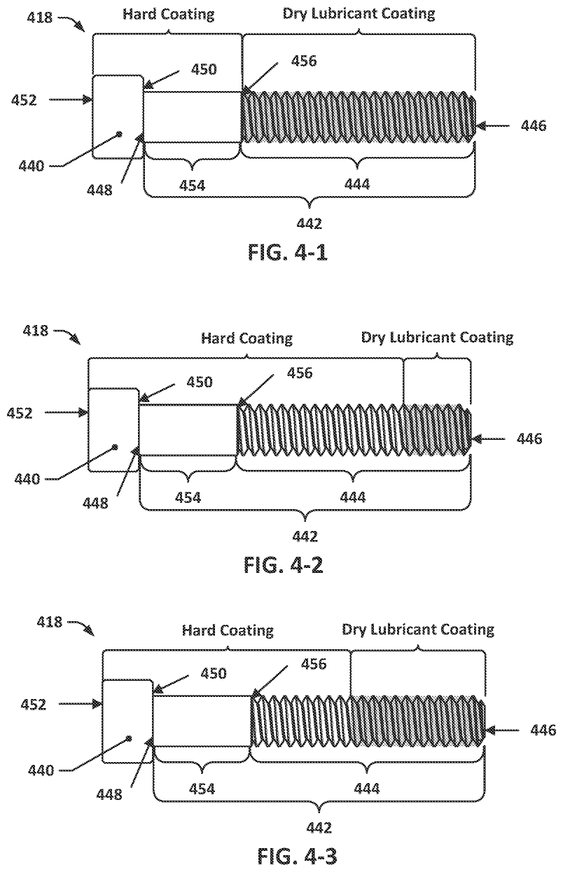

FIG. 4-1 shows a first example of a fastener 418 with two coatings that provide outermost surfaces of the fastener. In the first example, the hard coating, shown in white, provides the outer surfaces of the head 440 of the fastener 418 and the non-threaded portion 454 of the shank 442. The hard coating extends from the second side 452 of the head through the first side 450 of the head to the boundary 456 between the non-threaded portion 454 and the threaded portion 444. In each example of a fastener 418 where the shank 442 is partially threaded, the hard coating provides the outermost surfaces of at least the head 440 and the non-threaded portion 454 of the shank 442. The dry lubricant coating, shown in grey, provides the outermost surfaces of the entire threaded portion 444 of the fastener 418, starting at the end of the fastener 418, the first end 446 of the shank 442, and ending at the boundary 456. In each of the fasteners, the dry lubricant coating starts at the end of the fastener 418 which is the first end 446 of the shank 442.

FIG. 4-2 shows a second example of a fastener 418 with two coatings applied to the fastener. In the second example, the hard coating, shown in white, provides the outermost surfaces of the head 440 of the fastener 418 and part of the thread 444. The hard coating extends from the second side 452 of the head, past the first side 450 of the head, through the non-threaded portion 454 of the shank 442 and a significant way into the threaded portion 444. The dry lubricant coating, shown in grey, provides the outermost surfaces of a small part of the threaded portion 444 of the fastener 418. In the example shown, the dry lubricant coating is applied to the first six threads of the fastener 418 starting at the first end 446 of the shank 442.

FIG. 4-3 shows a third example of a fastener 418 with two coatings that provide the outermost surfaces of the fastener. The third example shows a fastener 418 with a hard coating that provides the outermost surfaces of the head 440, the non-threaded portion 454 of the shank 442, and part of the threaded portion 444 and a dry lubricant coating that provides the outermost surfaces of the shank from the end of the hard coating on the threaded portion to the first end 446 of the shank. The hard coating extends from the second side 452 of the head, past the first side 450 of the head, past the boundary 456 and partially towards the first end 446 of the shank 442. The dry lubricant coating, shown in grey, provides the outermost surfaces of a small portion of the threaded portion 444 of the fastener 418. The dry lubricant coating starts at the first end 446 of the shank 442 and ends about a little past halfway up the threaded portion 444.

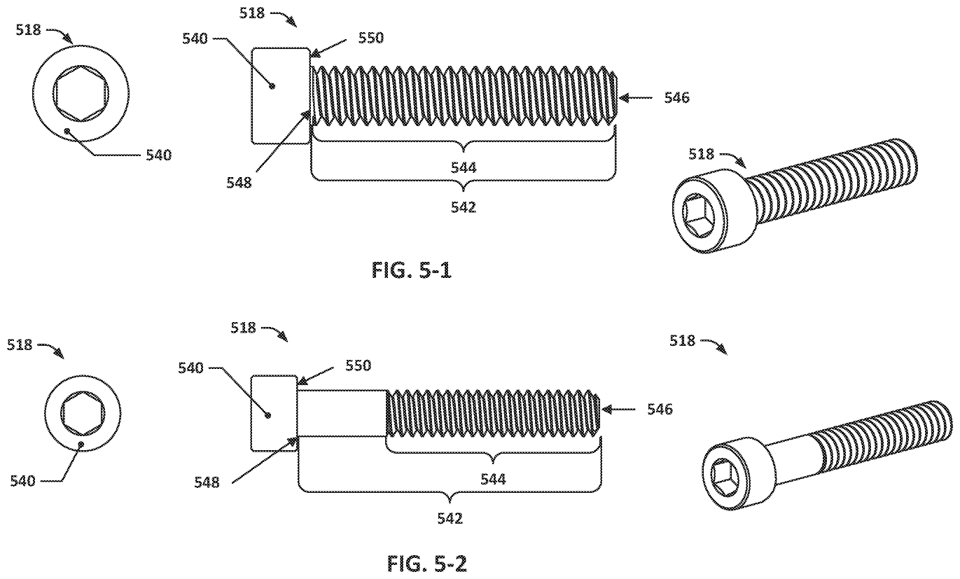

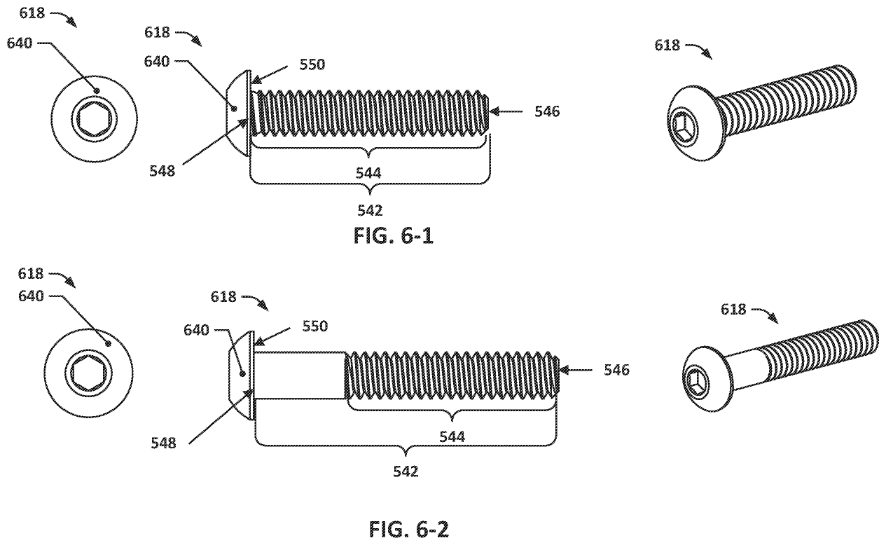

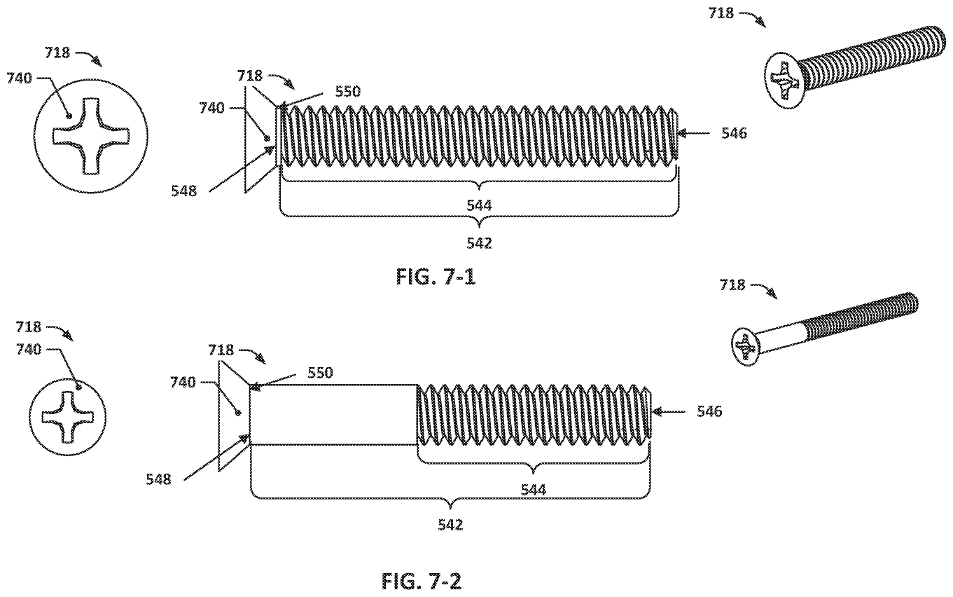

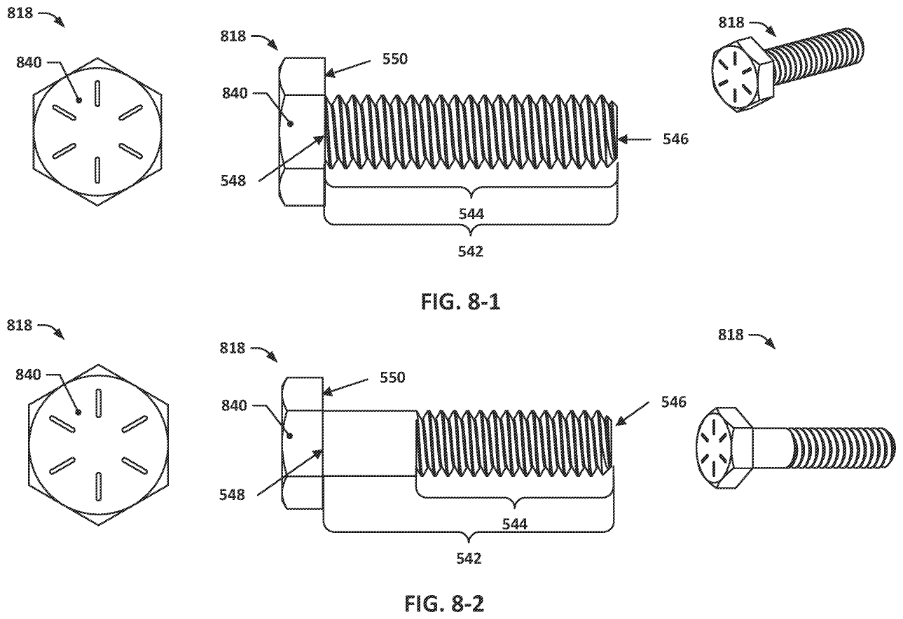

The type of fasteners used may depend on the application. FIGS. 5 through 8 show different types of example fasteners that may be used. For example, fasteners with different head types may be used. Example heads may include socket heads, button heads, countersink heads, hexagonal heads, pan heads, etc. The fasteners that may be used will, regardless of head type, have a shank. In some embodiments, the shank may be fully threaded. In some other embodiments, the shank may be partially threaded. No matter which fastener is used, each of the fasteners may have outermost surfaces provided by two different coatings, a hard coating and a dry lubricant coating. In all of the fasteners, the hard coating will provide the outermost surfaces of at least the head, and the dry lubricant coating will provide the outermost surfaces of at least a portion of the threads starting at the end of the shank opposite the end where the head is. In some embodiments, the dry lubricant coating may provide the outermost surfaces of the entire threaded portion of the fastener.

FIGS. 5 through 8 show different views of example fasteners. Each example fastener has a head and a shank 542. The shank 542 has a first end 546 and a second end 548. The second end 548 of the shank 542 is connected to a first side 550 of each of the heads. The shank 542 has a thread 544. In examples 5-1, 6-1, 7-1, and 8-1, the fastener is fully threaded, i.e., the fastener has a threaded portion 544 that extends from the first end 546 of the shank to the second end 548 of the shank. In example 5-2, 6-2, 7-2, and 8-2, the fastener is partially threaded, i.e., the threaded portion 544 extends only partway along the shank 542.

FIGS. 5-1 and 5-2 show different views of the example fastener 518. Each example fastener 518 has a head 540. The head 540 is a socket head. The socket head 540 can mate with a hexagonal-shaped (or Allen) wrench.

FIGS. 6-1 and 6-2 show different views of two example fasteners 618. Each example fastener 618 has a head 640. The head 640 is a button head with a hexagonal socket. In the examples shown, the button head 640 can mate with a hexagonal-shaped (or Allen) wrench.

FIGS. 7-1 and 7-2 show different views of yet another two example fasteners 718, each with a head 740. In these examples, each fastener 718 has a flat or countersunk head for the head 740 of the fastener. The head 740 has a cruciate recess that can mate with a Philips head screwdriver. Alternate implementations may have a straight slot or groove that may mate with a flat-head screwdriver; in some implementations, the head may have a hexagonal hole that may mate with a hexagonal screwdriver (or Allen drive).

FIGS. 8-1 and 8-2 show different views of two example fasteners 818. Each fastener 818 has a head 840. The head 840 is a hex head. The hex head 840 can mate with a wrench, such as a crescent or box wrench.

In some implementations, a controller may be used in a system that incorporates the fasteners discussed herein. FIG. 2 depicts a schematic of an example controller 160 with one or more processors 162 and a memory 164, which may be integrated with electronics for controlling the operation of valves 166 and/or a plasma generator 136 to allow the flow of plasma to the nozzle 132. The controller 160, depending on the processing requirements and/or the type of system, may be programmed to control any of the processes disclosed herein, such as processes for controlling the flow of plasma and/or cooling fluid, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing step, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example rotational indexers according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electrical connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Although the foregoing embodiments have been described in some detail for purposes of clarity of understanding, it will be apparent that certain changes and modifications may be practiced within the scope of the appended claims. It should be noted that there are many alternative ways of implementing the system and apparatus of the present embodiments. Accordingly, the present embodiments are to be considered as illustrative and not restrictive, and the embodiments are not to be limited to the details given here

1. A fastener comprising:
a head; and
a shank connected to a first side of the head, wherein:
a first portion of the shank is threaded;
a first zone extends from a second side of the head to at least the first side of the head;
a second zone covers at least a portion of the first portion;
an outermost surface of the fastener in the first zone is provided by a hard coating; and
an outermost surface of the fastener in the second zone is provided by a dry lubricant coating.

2. The fastener of claim 1, wherein the first portion includes the entire length of the shank.

3. The fastener of claim 1, wherein the first portion is less than the entire length of the shank.

4. The fastener in claim 1, wherein the second zone covers the entire first portion of the shank.

5. The fastener in claim 1, wherein the second zone covers less than the entire first portion of the shank.

6. The fastener in claim 1, wherein the dry lubricant coating is tungsten disulfide (WS₂).

7. The fastener in claim 1, wherein the dry lubricant coating is one of the following: tungsten disulfide (WS₂), molybdenum disulfide (MS₂), tin disulfide (SnS₂), bismuth trisulfide (Bi₂S₃), antimony trisulfide (Sb₂S₃), or any combination of two or more thereof.

8. The fastener in claim 1, wherein the hard coating is an alumina coating.

9. The fastener in claim 1, wherein the hard coating is one of the following: alumina, yttria-stabilized zirconia (YSZ), yttrium aluminum garnet (YAG), yttrium aluminum monoclinic (YAM), yttrium aluminum perovskite (YAP), or any combination of two or more thereof.

10. The fastener in claim 1, wherein the head is a socket head.

11. The fastener in claim 1, wherein the head is a button head.

12. The fastener in claim 1, wherein the head is a countersink head.

13. The fastener in claim 1, wherein the head is a hexagonal head.

14. The fastener in claim 1, wherein the head is a pan head.

15. A kit for use in a semiconductor wafer processing chamber, the kit comprising at least four of the fasteners of claim 1.

16. An apparatus comprising:
a spindle having an indexer hub with a plurality of indexer arms extending therefrom and a plurality of fasteners with exposed heads supported by the indexer hub, wherein:
each fastener of the plurality of fasteners has a shank connected to a first side of a head;
a first portion of the shank is threaded;
a first zone extends from a second side of the head to at least the first side of the head;
a second zone covers at least a portion of the first portion;
an outermost surface of the fastener in the first zone is provided by a hard coating; and
an outermost surface of the fastener in the second zone is provided by a dry lubricant coating.

17. The apparatus of claim 16 further comprising a chamber with four wafer processing stations, wherein the indexer hub is in a central area of the chamber.

18. The apparatus of claim 17 further comprising a remote plasma source, the remote plasma source configured to deliver plasma into the chamber and onto the indexer hub.

19. The apparatus of claim 16 wherein the dry lubricant coating is tungsten disulfide.

20. The apparatus of claim 16 wherein the hard coating is an alumina coating.
